(19) United States
(12) Patent Application Publication
(10) Pub. No.: US 2024/0282875 A1
(43) Pub. Date: Aug. 22, 2024

(54) WINDOW UNIT FOR A BUILDING OR STRUCTURE

(71) Applicant: CLEARVUE TECHNOLOGIES LTD, West Perth (AU)

(72) Inventors: Steven COONEN, Grass Valley, CA (US); Victor ROSENBERG

(73) Assignee: CLEARVUE TECHNOLOGIES LTD, West Perth, WA (AU)

(21) Appl. No.: 18/170,996

(22) Filed: Feb. 17, 2023

(51) Int. Cl. H01L 31/048; A01G 9/24

(52) U.S. Cl. CPC H01L 31/0488; A01G 9/243; H01L 31/0481

(57) ABSTRACT

The present disclosure provides a window for a building or structure. The window comprises first and second panels which have major surfaces and are at least largely transmissive for visible light. The second panel has major surfaces which are smaller than the major surfaces of the first panel. Further, the second panel is positioned parallel to the first panel such that the second panel is within a projection of the circumference of the first panel in a direction along the surface normal of the first panel. The first and second panels are laminated together. The first and second panels are arranged such that the first panel has a border region which extend beyond the circumference of the second panel and the laminated first and second panels can be supported at the border region of the first panel.

### FIELD OF THE INVENTION

The present disclosure relates to a window for a building or structure and relates particularly, though not exclusively, to window for a greenhouse structure and which generates electricity.

### BACKGROUND OF THE INVENTION

Many buildings, such as greenhouse structures, have large glass panels through which sunlight penetrates. Existing greenhouse structures typically comprise a frame structure and single glazed windows. PCT international application number PCT/AU2020/050746 in the name of the present applicant discloses a window panel for greenhouse structures. The disclosed window panel has a filtering layer and filters a portion of incident sunlight in order to improve conditions for growing plants. Further, the disclosed window panel has in one variation solar cells which convert some of the incident solar light into electricity.

### SUMMARY OF THE INVENTION

The present invention provides in a first aspect a window for a building or structure, the window comprising:
a first panel having first and second major surfaces and being at least largely transmissive for visible light;
a second panel having first and second major surfaces which are smaller than the first and second major surfaces of the first panel, the second panel being at least largely transmissive for visible light and being positioned parallel to the first panel such that the second panel is within a projection of the circumference of the first panel in a direction along the surface normal of the first panel;
wherein the first and second panels are laminated together; and
wherein the first and second panels are arranged such that the first panel has a border region which extends beyond the circumference of the second panel and the laminated first and second panels can be supported at the border region of the first panel.

The first and second panels are typically arranged such that the laminated first and second panels can be supported at the border region of the first panel by a window frame, such as a window frame of a greenhouse, sized or having fittings for receiving a single panel for forming a single glazed window. Embodiments of the present invention consequently provide the advantage that even laminated multi-panels can be received and supported by a frame designed for receiving a single glazed panel and forming a single glazed window.

The window may comprise a window frame designed for supporting a panel for a single glazed window and which supports the laminated first and second panels at the border region of the first panel.

The border region of the first panel may have a width of 2-5 cm, 5-10 cm, 10-15 cm or even 15-20 cm. The border region of the first panel may have an exposed surface area or may be covered by an exposed coating.

Alternatively or additionally, a supportive element, such as a sheet of a metallic or polymeric material may cover at least portions of the border region of the first panel directly or indirectly and may also be partially positioned between the first and second panels.

Further, the border region of the first panel may be at least partially enclosed by a support structure which may have a substantially U-shaped cross-section and in which at least portions of the border region of the first panel may be positioned. The support structure may be arranged to provide further stability to the border region of the first panel and may be formed from a suitable metallic or polymeric material, such as a hard plastics material. A layer of a polymeric material (which may be rubber-like or may be a foam) may be positioned between the support structure and the border region of the first panel.

The first and second panels may be laminated together using a sandwich layer including polyvinylbutyral (PVB) or another suitable lamination material.

The window may also comprise a third panel which may be positioned parallel to and spaced apart from the second panel. The window may comprise a spacer which spaces the third panel from the second panel wherein the first panel, the second panel and the spacer define an interior space. Primary and secondary seals comprising butyl or the like may be applied around the spacer and seal the interior space such that an insulated glass unit (IGU) is formed. The support structure may also be formed to support and the third panel at a border region of a major surface facing away from the second panel.

The window may comprise a plurality of solar cells distributed across one of the major surfaces of the first panel or a surface parallel to the major surfaces of the first panel. The solar cells of the plurality of solar cells may be positioned between the first and second panels and may be embedded within a lamination material, such as the polyvinylbutyral (PVB).

The solar cells may be bifacial solar cells and adjacent solar cells may be arranged in an overlapping or “shingled” relationship.

The solar cells may be evenly distributed across one of the major surfaces of the first panel or a surface parallel to the major surfaces of the first panel. For example, the solar cells may be arranged in islands. The solar cells may be arranged in regular formed structures or irregular formed structures. For example, the solar cells may be arranged in strips or squares or other rectangular structures or other geometrical shapes which are evenly or randomly distributed across one of the major surfaces of the first panel.

The solar cells may also be arranged in a plurality of strips which are parallel to each other and may be evenly or unevenly spaced apart.

The solar cells may also form a plurality of islands which are evenly or unevenly distributed such that a two-dimensional array is formed. Further, the solar cells may be distributed in a predetermined pattern or design and may form for example writing or a visual representation.

Alternatively or additionally, the window may comprise a solar cell provided in the form of a thin film coating on a surface one of the major surfaces of the first or second panels. The thin film coating typically is semi-transparent for visible light. In one embodiment the thin film comprises cadmium telluride, but may alternatively comprise another suitable material.

Further, the window may comprise a solar selective coating on at least one of the major surfaces of the first and second panels, the solar selective coating being arranged to filter incident sunlight within predetermined wavelengths range such that transmission of sunlight within the predetermined wavelengths range is at least reduced or avoided.

The predetermined wavelengths range may include wavelengths in a range in which the light is not beneficial for the growth of plants. Alternatively or additionally, the solar selective coating may be arranged to absorb a portion of incident sunlight and emit light in a wavelength range in which the light is beneficial for the growth of plants. For example, the solar selective coating may comprise a suitable luminescent material which absorbs a portion of incident sunlight and emits luminescence radiation in a wavelengths range in which the light is beneficial for the growth of plants.

The building or structure may be a greenhouse structure and embodiments of the present invention consequently facilitate the growth of plants in the greenhouse structure.

In one specific embodiment of the present invention the predetermined wavelengths range includes an infrared wavelengths range and/or a wavelengths range within the visible wavelengths range and/or a wavelengths range within the ultraviolet wavelengths range.

The solar selective coating is in one exemplary embodiment particularly suitable for growing lettuce and the predetermined wavelengths range includes wavelength ranges from 300 nm to 400 nm, and from 500 nm to 600 nm.

The solar selective coating may be a multi-layered interference coating.

The present invention provides in a second aspect a greenhouse structure comprising a window for a building or structure in accordance with the first aspect of the present invention.

The invention will be more fully understood from the following description of specific embodiments of the invention. The description is provided with reference to the accompanying drawings.

### BRIEF DESCRIPTION OF THE DRAWINGS

FIGS. 1 and 2 are schematic representations of top-views of components of a window for a building or structure in accordance with embodiments of the present invention; and

FIGS. 3 and 4 are schematic cross-sectional representations of portions of window for a building or structure in accordance with embodiments of the present invention.

### DETAILED DESCRIPTION OF EMBODIMENTS

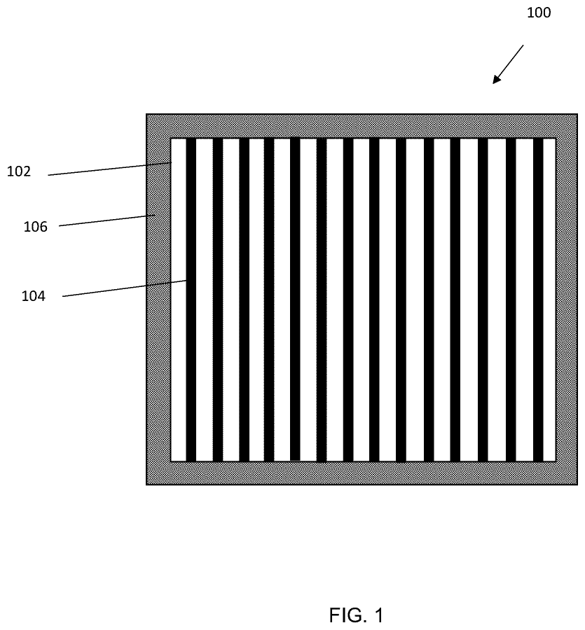

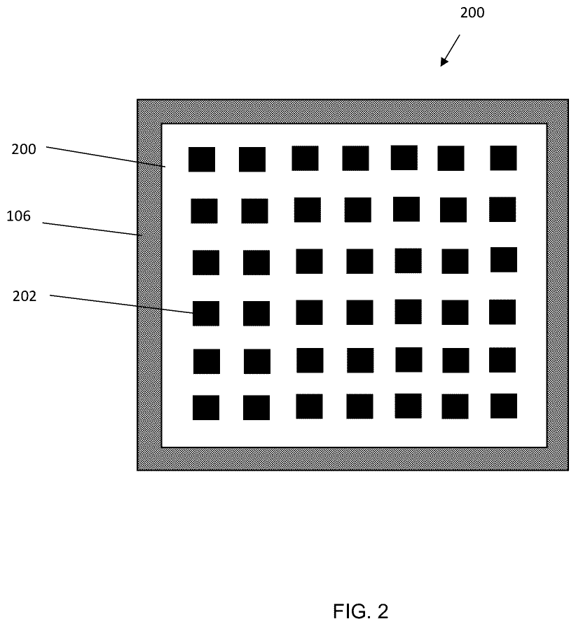

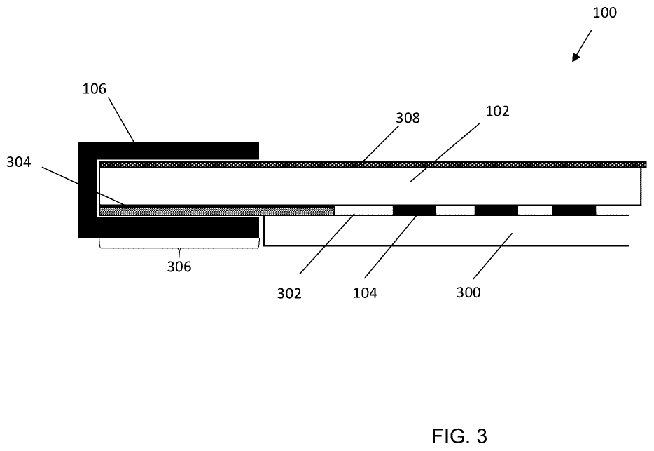

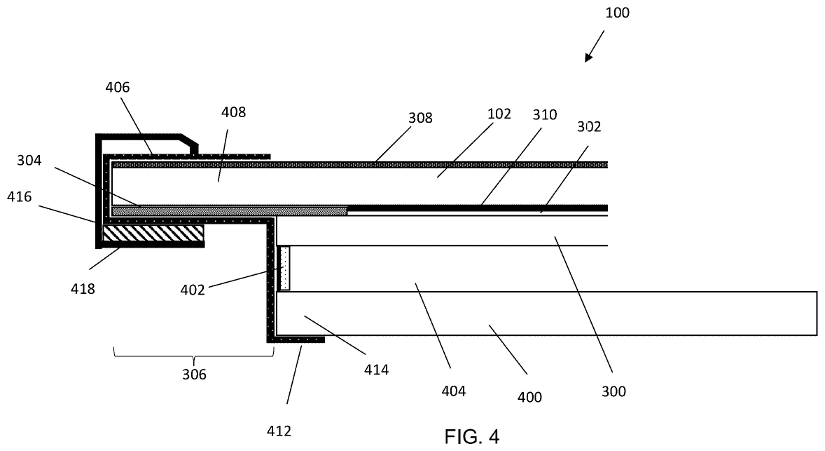

Referring initially to FIG. 1, there is shown a top view of a window for a structure or building in accordance with an embodiment of the present invention. The window 100 comprises a first panel 102 and a second panel 300. The second panel 300 is not shown in FIGS. 1 and 2 as it is positioned below the first panel 102, but is shown in FIGS. 3 and 4 which will be described further below. The first and second panels 102, 300 are parallel to each other. The window 100 further comprises a plurality of solar cell strips 104 which are sandwiched between the first panel 102 and the second panel 300 which are laminated together. The solar cell strips 104 are electrically interconnected. The solar cells are bifacial solar cells and are in each strip arranged in an overlapping or (“shingled”) relationship. The first panel 102 and the second panel 300 are in this embodiment formed from an ultra-clear low iron glass. In this embodiment the first panel 102 (or front-panel”) has a thickness of 3.2 mm and the second panel (or “back-panel”) has a thickness of 2 mm.

The window 100 further comprises a frame 106 which supports the first panel 102 within a border region or edge region. The frame may for example be formed from extruded aluminium portions. The first panel 102 is larger than the second panel 300 and a border region of the first panel 102 extends beyond the circumference of the second panel 300.

FIG. 2 shows a window 200 in accordance with another embodiment of the present invention. The window 200 is related to the window 100 and like components are given like reference numerals. The window 200 comprises the first panel 102 and the second panel (not shown). A plurality of solar cell grouped in islands of solar cells 202 are sandwiched between the first panel 102 and the second panel and are electrically interconnected. The first panel 102 and the second panel are laminated together and the window 200 comprises the frame 106 which, similar to the window 100 described above, supports that first panel 102 within a border region, but does not directly support the second panel.

As an alternative or in addition to the solar cell islands 202 or solar cell strips 104 the window may comprise a solar cell provided in the form of a thin film coating, such as a thin film comprising CdTe, which is semi-transparent for visible light. The thin film coating is not shown in FIGS. 1 and 2, but will be illustrated below with reference to FIG. 3. Further, the window may comprise a solar selective coating (“filter layer”) applied to one of the major surfaces of the first and second panels and arranged to filter incident sunlight in order to improve growth conditions of plants in the greenhouse structure. The solar selective coating is not shown in Figures and 2 and will also be described below with reference to FIG. 3.

FIG. 3 is a cross-sectional representation of a portion of the window 100 described above and like components are given like refence numerals. FIG. 3 shows the first panel 102 and the second panel 300. The strips of solar cells 104 are sandwiched between the first and second panels 102, 300 and are embedded within a lamination material 302, which in this embodiment is polyvinylbutyral (PVB). Attached to the first panel 102 is also a sheet of a supporting material 304, which in this embodiment is formed from aluminium or a hard plastics material. The sheet of supporting material 304 is adhered to the first panel 102 using the PVB material 302.

A person skilled in the art will appreciate that the support sheet 304 may be provided in any suitable form, and may also be formed from any suitable metal other than aluminium or any suitable polymeric material. Further, in a variation of the described embodiment the window 100 may not include the support sheet 304.

The first panel 102 has a border region 306 which includes the circumference of the first panel 102 and extends beyond the circumference of the second panel 300, which is smaller than the first panel 102. The frame 106 supports the first panel 102 within the border region 306, but does not directly support the smaller second panel 300. This arrangement has the advantage that the panels can be fitted to a window frame designed for forming a single glazed window, such as the window frame of a typical greenhouse structure. The border region 306 has in this embodiment a width which is uniform along edges of the first panel 102. The width of the border region is approximately 15 cm, but may alternatively also be smaller (such as 5-10 cm or 10-15 cm) or larger (such as 15 to 20 cm).

FIG. 3 also shows the solar selective coating 308. In this embodiment the solar selective coating 308 is provided in the form of a multi-layered interference coating. Materials and layer thicknesses of the solar selective coating 308 are chosen such that predominantly sunlight which is beneficial for the growth of plants, in this embodiment lettuce, are allowed to transmit into an interior of the greenhouse structure. More specifically, the solar selective coating 308 is arranged to reduce transmission of incident sunlight in the wavelength ranges from 300 nm to 400 nm and from 500 nm to 600 nm. The filter layer 308 comprises a stack of layers which have suitable materials and thicknesses. A person skilled in the art will appreciate that optical interference layers having a desired transmission profile can be designed without the need of experimentation using known procedures.

In a variation of the described embodiment the solar selective coating 308 may comprise a luminescent material which absorbs a portion of incident sunlight and emits luminescence light in a wavelengths range in which light is beneficial for the growth of plants.

The solar selective coating 308 is in this embodiment located at an outside surface of the first panel 102. The person skilled in the art will also appreciate that alternatively the solar selective 308 may be positioned at an inside surface of the first panel 102 or on a surface of the second panel 300 or may be excluded from the first panel 102 or the window 100.

FIG. 4 illustrates a further variation of the window 100 and like components are given like reference numerals. In this embodiment the window 100 does not include the solar cells 104, but instead comprises a thin film solar cell 310 positioned on a major surface of the first panel 102 and between the first and second panels 102, 300. The thin film solar cell 310 comprise in this embodiment CdTe and is semi- transmissive for visible light. A person skilled in the art will appreciate that the thin film solar cell 310 may alternatively comprise other suitable materials and may be positioned on other surfaces of the first panel 102 or the second panel 300. The thin film solar cell is also adhered to the second panel 300 by a lamination material, such as the PVB material 302, which is also positioned between the second panel 300 and the thin film solar cell 310 and could comprise materials instead of CdTe.

Further, the window 100 comprises in this embodiment a third panel 400 which is spaced apart from the second panel 300 by a spacer structure 402. First and second seals comprising butyl and silicone, respectively, seal an interior space 404 and are applied over the spacer 402 such that an insulated glass unit (IGU) is formed.

The window 100 also comprises a support structure 406 which encloses a border region 408 of the first panel 102 at three sides and which is substantially U-shaped in cross-section. The support structure provides further stability to the border region 408 of the first panel and is formed from a suitable metallic or polymeric material, such as a hard plastics material. A layer of a rubber-like polymeric material (not shown) may be positioned between the support structure and surfaces of the border region 408 of the first panel 102.

The support 406 has in this embodiment also an extension 412 which is shaped to support a border region 414 of the third panel 400. Further, the window 100 has in this embodiment a frame structure 416 which indirectly supports the first panel at the border region 408 via the support structure 406 and optionally also via a layer of a polymeric material 418 (which may comprise a rubber-like or foam material).

The lamination of components of the window 100, 200 will now be described in further detail. Initially a sheet of PVB is positioned between the first panel 102 and the strips of solar cells 104 or the islands of solar cells 202 and the support sheet 304. Bonding of the strips of solar cells 104 or the islands of solar cells 202 and the support sheet to the first panel 102 is effected by applying heat to the sheet of the PVB material. An additional sheet of the PVB material is positioned over the strips of solar cells 104 or the islands of solar cells 202 and a portion of the support sheet 304. The second panel 300 is then be positioned on exposed surfaces of the PVB sheet(s) and is bonded to the exposed surfaces of the PVB sheet by the application of further heat such that a laminated structure is formed and the solar cells 104, 202 with and a portion of the support sheet 304 are sandwiched between the first and second panels.

The solar cells of the strips 104 or islands 202 are typically silicon-based bifacial solar cells, but may alternatively also comprises other materials and may not necessarily be bifacial or arranged in a shingled manner.

A person skilled in the art will appreciate that variations of the described embodiments are possible within the scope of the present invention. For example, a lamination material other than PVB may be used. Further the filter layer 308 may have any suitable optical transmission properties. In addition, the solar cells may be distributed across a surface of the window in any regular or irregular manner. Further, in variation of the described embodiments the window may not comprise any solar cells and may also not comprise the filter layer. In addition, the first and second panels may have any suitable thickness. Further the support structure and the frame, which the windows 100, 200 may comprise, may have any suitable shape.

Any discussion of the background art throughout this specification should in no way be considered as an admission that such background art is prior art, nor that such background art is widely known or forms part of the common general knowledge in the field in Australia or worldwide.

1. A window for a building or structure, the window comprising:
a first panel having first and second major surfaces and being at least largely transmissive for visible light;
a second panel having first and second major surfaces which are smaller than the first and second major surfaces of the first panel, the second panel being at least largely transmissive for visible light and being positioned parallel to the first panel such that the second panel is within a projection of the circumference of the first panel in a direction along the surface normal of the first panel; and
a plurality of solar cells positioned between the first and second panel, the plurality of solar cells being arranged to allow light to pass between adjacent solar cells such that a combination of the first panel, the second panel and the plurality of solar cells is at least partially transmissive for light;
wherein the first and second panels are bonded to one another; and
wherein the first and second panels are arranged such that the first panel has a border region which extends beyond the circumference of the second panel and the laminated first and second panels can be supported at the border region of the first panel.

2. The window of claim 1 wherein the first and second panels are arranged such that the laminated first and second panels is configured to be supported at the border region of the first panel by a window frame, such as a window frame of a greenhouse, sized or having fittings for receiving a single panel for forming a single glazed window.

3. The window of claim 1 comprising a window frame designed for supporting a panel for a single glazed window and which supports the laminated first and second panels at the border region of the first panel.

4. The window of claim 1 wherein the border region of the first panel has a width of 2-5 cm, 5-10 cm, 10-15 cm or even 15-20 cm.

5. The window of claim 1 wherein the border region of the first panel is an exposed surface area or is covered by an exposed coating.

6. The window of claim 1 wherein a sheet of a metallic or polymeric material covers at least portions of the border region of the first panel directly or indirectly and is also partially positioned between the first and second panels.

7. The window of claim 1 wherein the border region of the first panel is at least partially enclosed by a support structure which has a substantially U-shaped cross-section and in which at least portions of the border region are positioned.

8. The window of claim 1 comprising a third panel positioned parallel to and spaced apart from the second panel, the window further comprising a spacer which spaces the third panel from the second panel wherein the window is arranged such that an insulated glass unit (IGU) is formed.

9. (canceled)

10. The window of claim 1, wherein the laminated first and second panels sandwich the solar cells.

11. The window of claim 1, wherein the solar cells are bifacial solar cells and adjacent solar cells are arranged in an overlapping or “shingled” relationship.

12. The window of claim 1, wherein the solar cells are evenly distributed across one of the first and second major surfaces of the first panel or a surface parallel to the first and second major surfaces of the first panel.

13. The window of claim 1, wherein the solar cells are arranged in regular formed structures.

14. The window of claim 1, wherein the solar cells are arranged in irregular formed structures.

15. The window of claim 1, wherein the solar cells are arranged in islands.

16. The window of claim 1, wherein the solar cells are arranged in strips or squares.

17. The window of claim 1, wherein the solar cells are arranged in a plurality of strips which are parallel to each other and are evenly or unevenly spaced apart.

18. The window of claim 1 wherein the solar cells form a plurality of islands which are even distributed such that a two-dimensional array is formed and/or wherein the solar cells are distributed so as to form a predetermined pattern or design.

19. The window of claim 1 comprising a solar cell provided in the form of a thin film coating on at least one of the major surfaces of the window.

20. The window of claim 19 wherein the thin film coating comprises cadmium telluride.

21. The window of claim 1 comprising a solar selective coating on at least one of the major surfaces of the first and second panels, the solar selective coating being arranged to filter incident sunlight within a predetermined wavelengths range such that transmission of sunlight within the predetermined wavelengths range is at least reduced or avoided.

22. The window of claim 21 wherein the predetermined wavelengths range includes wavelengths range in which the light is not beneficial for the growth of plants.

23. The window of claim 21 wherein the solar selective coating is arranged to absorb a portion of incident sunlight and remit light in a wavelength range in which the light is beneficial for the growth of plants.

24. The window of claim 21 wherein the building or structure is a greenhouse structure and wherein the window facilitates the growth of plants in the greenhouse structure.

25. The window of claim 21 wherein the predetermined wavelengths range includes an infrared wavelengths range and/or a wavelengths range within the visible wavelengths range and/or a wavelengths range within the ultraviolet wavelengths range.

26. The window of claim 21 wherein the solar selective coating is a multi-layered interference coating.

27. A greenhouse structure comprising a window for a building or structure in accordance with claim 1.
